(19) United States
(12) Patent Application Publication
(10) Pub. No.: US 2009/0153488 A1
(43) Pub. Date: Jun. 18, 2009

(54) Keyboard, Input Method, and Information Processing Apparatus

(75) Inventors: Takako Suzuki, Nerima-ku (JP); Yoshinori Wakizaka, Meguro-ku (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/262,040

(22) Filed: Oct. 30, 2008

(30) Foreign Application Priority Data
Dec. 12, 2007 (JP) 2007-321291

(51) Int. Cl. G06F 3/02; H03M 11/00

(52) U.S. Cl. 345/168; 341/22

(57) ABSTRACT

A keyboard includes: a key panel that includes: a plurality of keys that are respectively assigned to input characters and symbols, the keys including a specific key that is assigned to input a pair of characters by a single keystroke; and a plurality of switches that are provided for each of the keys to output an electrical signal unique to each of the keys when the keys are pressed; and a controller that detects the electrical signal output from the key panel and outputs a key code corresponding to the electrical signal, the controller being configured to operate to: determine whether the specific key is pressed by detecting the electrical signal; and output multiple key codes including key codes corresponding to the pair of characters when determined that the specific key is pressed.

### CROSS-REFERENCE TO RELATED APPLICATIONS

This application is based upon and claims the benefit of priority from Japanese Patent Application No. 2007-321291, filed on Dec. 12, 2007, the entire content of which are incorporated herein by reference.

### BACKGROUND

1. Field

One embodiment of the present invention relates to an input device, such as a keyboard, for an information processing apparatus to input characters and symbols.

2. Description of the Related Art

A keyboard is used as an input device of an information processing apparatus, such as a PC (Personal Computer). Characters and symbols are printed on a key top of each keys provided in the keyboard. To input characters and symbols, a user types desired keys, thereby instructing the PC to input the characters or symbols printed on the keys.

However, there is a limitation in a conventional keyboard that the number of characters or symbols input by a single key stroke is one. For example, in characters and symbols represented by a pair of left and right such as parentheses, although it is assumable in advance that the pair of parentheses are to be input, twice or more times of key stroke are required.

As a method for inputting parentheses, there is proposed a method of optimizing input at a time of converting a predetermined character string into Chinese/Kanji characters through an input method editor. An example of such method is disclosed in JP-A-2000-163412.

However, according to the conventional method, a user is required to type the keys twice, key for left and key for right, for inputting left and right of characters or symbols used as a pair. In a case where the user uses a kandi conversion function, which converts input alphabets and kana-characters into kanji-characters, the user is also required to input several redundant keys for activating the kanji conversion function and selecting appropriate kanji-characters.

### SUMMARY

According to a first aspect of the present invention, there is provided a keyboard including:

a key panel that includes: a plurality of keys that are respectively assigned to input characters and symbols, the keys including a specific key that is assigned to input a pair of characters by a single keystroke; and a plurality of switches that are provided for each of the keys to output an electrical signal unique to each of the keys when the keys are pressed; and a controller that detects the electrical signal output from the key panel and outputs a key code corresponding to the electrical signal, the controller being configured to operate to: determine whether the specific key is pressed by detecting the electrical signal; and output multiple key codes including key codes corresponding to the pair of characters when determined that the specific key is pressed.

According to a second aspect of the present invention, there is provided an input method for inputting characters and symbols using a keyboard, the method including: determining whether a specific key provided on the keyboard is selected, the specific key being assigned to input a pair of characters by a single keystroke; and output multiple key codes including key codes corresponding to the pair of characters when determined that the specific key is selected.

According to a third aspect of the present invention, there is provided an information processing apparatus including: a keyboard that includes: a plurality of keys that are respectively assigned to input characters and symbols, the keys including a specific key that is assigned to input a pair of characters by a single keystroke; and a plurality of switches that are provided for each of the keys to output an electrical signal unique to each of the keys when the keys are pressed; a controller that detects the electrical signal output from the key panel and outputs a key code corresponding to the electrical signal, the controller being configured to operate to: determine whether the specific key is pressed by detecting the electrical signal; and output multiple key codes including key codes corresponding to the pair of characters when determined that the specific key is pressed; and a display unit that displays characters corresponding to the key code output from the controller at a caret position.

### BRIEF DESCRIPTION OF THE SEVERAL VIEWS OF THE DRAWINGS

A general configuration that implements the various feature of the invention will now be described with reference to the drawings. The drawings and the associated descriptions are provided to illustrate an embodiment of the invention and not to limit the scope of the invention.

FIG. 1 is a diagram illustrating an example of an information processing apparatus according to an embodiment of the present invention.

FIG. 2 is a block diagram illustrating an example of an information processing apparatus according to the embodiment.

FIG. 3 is a diagram illustrating an example of a conventional keyboard.

FIG. 4 is a diagram illustrating an example of keys of the conventional keyboard to which parentheses are assigned.

FIG. 5 is a diagram illustrating an example of a key according to the embodiment.

FIG. 6 is a diagram illustrating an example of an input screen according to the embodiment.

FIG. 7 is a diagram illustrating another example of keys according to the embodiment.

FIG. 8 is a diagram showing an example of a block configuration of a keyboard according to the embodiment.

FIG. 9 is a flowchart illustrating an example of key input according to the embodiment.

### DETAILED DESCRIPTION

An embodiment of the present invention will be described with reference to the drawings.

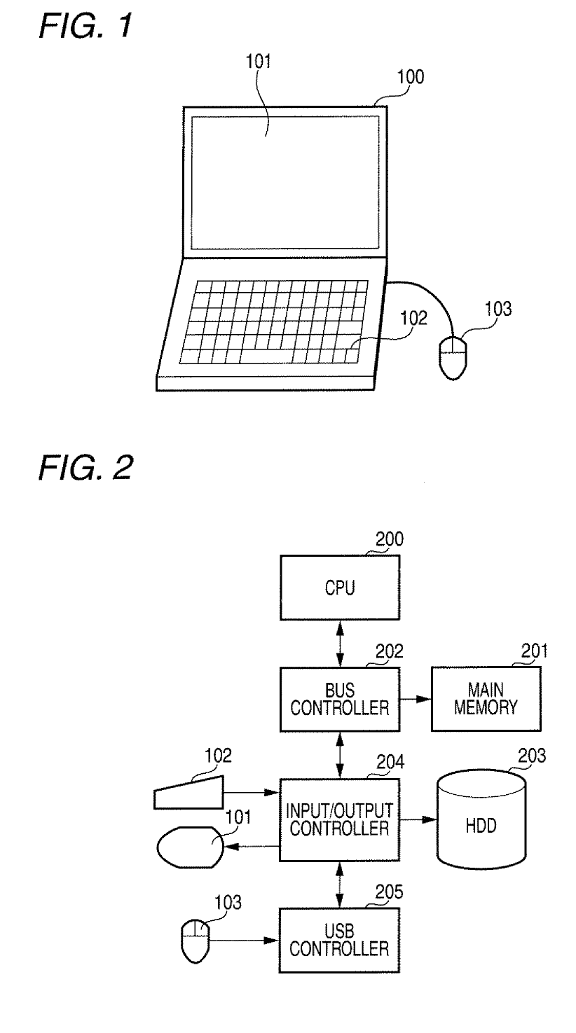

FIG. 1 is a diagram illustrating an example of an information processing apparatus according to an embodiment of the present invention. As shown in FIG. 1, a PC 100, which is an example of the information processing apparatus, includes a display 101 and a keyboard 102 and is connected with a mouse 103.

The PC 100 is, for example, a portable computer such as a notebook PC. The display 101 is a display device, such as a LCD (Liquid Crystal Display) panel, which is provided in the PC 100. The PC 100 displays information to a user by displaying characters, symbols and images on the display 101.

The keyboard 102 is an input device provided in the PC 100. A user using the PC 100 inputs instructions into the PC by typing keys provided in the keyboard 102.

The mouse 103 is an input device for moving a mouse cursor displayed on the display 101. Such an input device is also called a pointing device, from the viewpoint to point a predetermined position on the screen. The mouse 103 is provided with several buttons for inputting instructions into the PC 100 to perform various operations.

FIG. 2 is a block diagram illustrating an example of an inner configuration of the PC 100 according to the embodiment. As shown in FIG. 2, the PC 100 is provided with a CPU 200, a main memory 201, a bus controller 202, a HDD 203, an input/output controller 204, and a USB controller 205.

The CPU 200 is a central processing unit, and controls other components provided in the information processing apparatus 100. The CPU 200 has a function of performing various processes according to a program while executing the program.

The main memory 201 is configured by a semiconductor memory device, and is used as an area for storing a program and data used by the CPU 200 when executing the program.

The bus controller 202 has a function of controlling a bus to transmit information among various components of the information processing apparatus 100. The CPU 200 instructs to read and write data in the main memory 201 through the bus, or instructs other components.

The HDD 203 is a mass storage device configured by a magnetic disk device (Hard Disk Drive). The HDD 203 stores applications executed by the CPU 200 or data necessary at the time of execution, and the HDD 203 transmits and receives them to and from the CPU 200 through the bus controller 202 as necessary.

The input/output controller 204 has a function of providing an interface with the CPU 200, the HDD 203, the display device 101, and various types of input/output devices such as the keyboard 102.

The USB controller 205 is a control device for connecting devices having the USB (Universal Serial Bus) standard interface. There are various types of devices as devices based on the USB standard. The devices can be freely connected and disconnected by the PnP (Plug and Play) technique even when the information processing apparatus 100 is operating. In the embodiment, the USB controller 205 is used to connect the mouse 103.

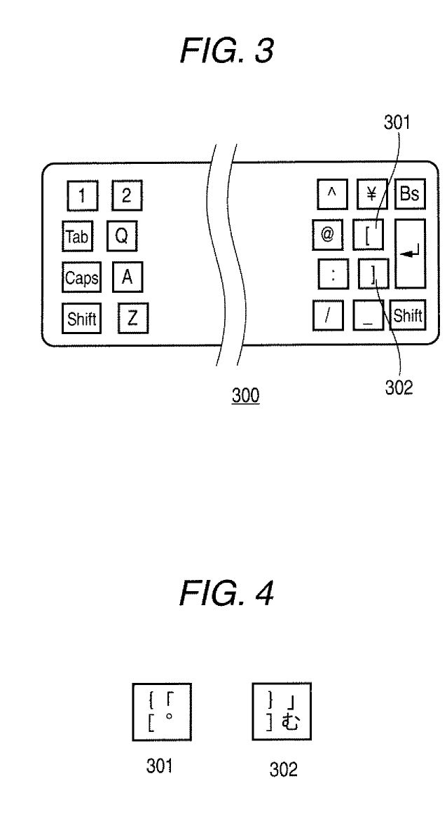

FIG. 3 is a diagram illustrating an example of a conventional keyboard. FIG. 3 shows a keyboard 300 and parenthesis keys 301 and 302 provided in the keyboard 300.

The keyboard 300 illustrates an example of key arrangement in a Japanese keyboard.

The parenthesis key 301 is a key assigned for inputting a bracket “[”. In the keys provided in the keyboard 300, various types of characters or symbols are selectively input by combining other special key such as a shift key. Various characters or symbols are printed on key tops of each of the keys. In the description, the characters and symbols are simply and collectively called “characters”.

The parenthesis key 302 is a key assigned for inputting a bracket “[”. Generally, when bracket keys are used for inputting characters, the left bracket “[” and the right bracket “]” are used as one pair to bracket a predetermined character string.

FIG. 4 is a diagram illustrating an example of keys to which parentheses are assigned in the conventional keyboard. The parenthesis keys 301 and 302 are shown in FIG. 4. As shown in the FIG. 4, four characters are printed on each of the parenthesis keys 301 and 302. Three types of left parenthesis symbols are assigned to the parenthesis key 301, and three types of right parenthesis symbols are assigned to the parenthesis key 302. The three types of parenthesis symbols are changed to one another according to any one of a case of typing the key, a case of typing the key together with the shift key, and a case of typing the key by changing an input mode.

In any case, to input the left parenthesis and the right parenthesis, a user is required to type the keys at least twice.

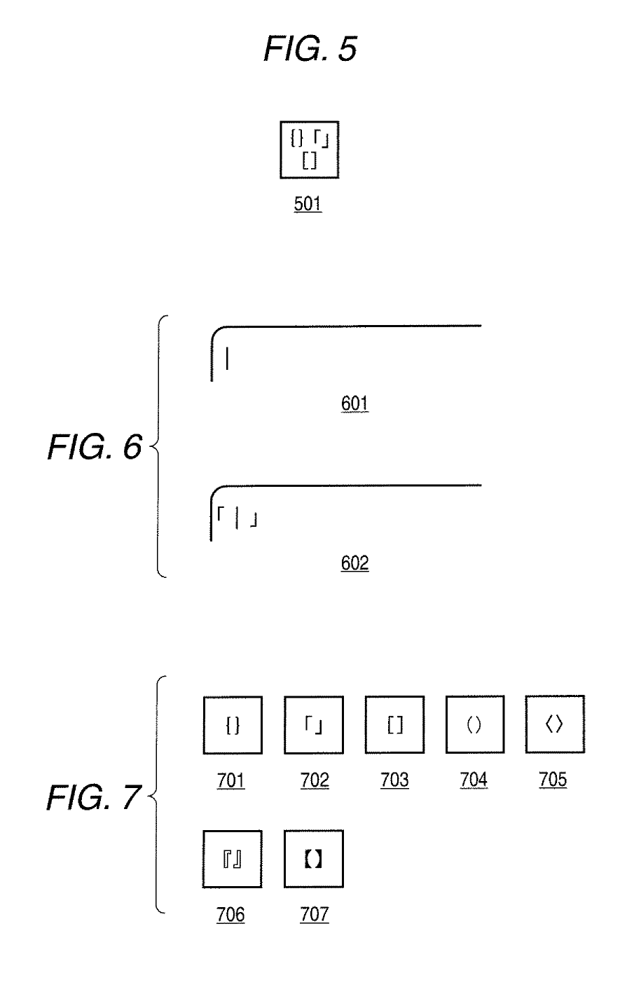

FIG. 5 is a diagram illustrating an example of a key according to the embodiment. Left parentheses and right parentheses are printed on the parenthesis key 501, and a pair of left and right parentheses that forms a pair of the parenthesis symbols are input according to an input mode by typing once. For example, it is general that the left parenthesis is input following to a word or phrase about which supplementary explanation is more necessary, a supplementary sentence is described, and then the description is finished by the right parenthesis. There are many cases that a word to be emphasized in a sentence is bracketed by the parentheses. In consideration of this, when the parentheses are used in the sentence, it may be more convenient to input the same kind of parenthesis symbols (e.g., “{}” and “[]”) by a pair of left and right once, because the number of typing decreases.

FIG. 6 is a diagram illustrating an example of input screens according to the present embodiment. FIG. 6 shows how a caret indicating an input position is moved when the parenthesis key 501 is typed.

An input screen 601 shows a screen on which a caret is positioned at a character input position displayed on the display 101. In the figure, the caret is positioned at the left end.

An input screen 602 shows a screen when the parenthesis key 501 is typed once in a state where the input screen 601 is displayed. This example is a case of inputting a pair of brackets, and a caret is displayed within the brackets after inputting the brackets. A user can continuously input a sentence without operating other keys to return the position of the caret to be positioned between the parentheses.

When the left bracket and the right bracket are sequentially input by using a conventional keyboard, the caret indicating the input position moves to a position right to the right bracket. In this case, the user needs to reset the position of the caret by typing other keys, such as a left cursor key. When using a front end processor (FEP) such as an IME, the user is also required to input some extra operation for performing character conversion and for resetting the position of the caret.

FIG. 7 is a diagram illustrating another example of keys according to the embodiment. There are several characters or symbols represented by one pair of left and right, and some examples of parenthesis keys 701 to 707 for inputting those pairs of characters and symbols are shown in FIG. 7.

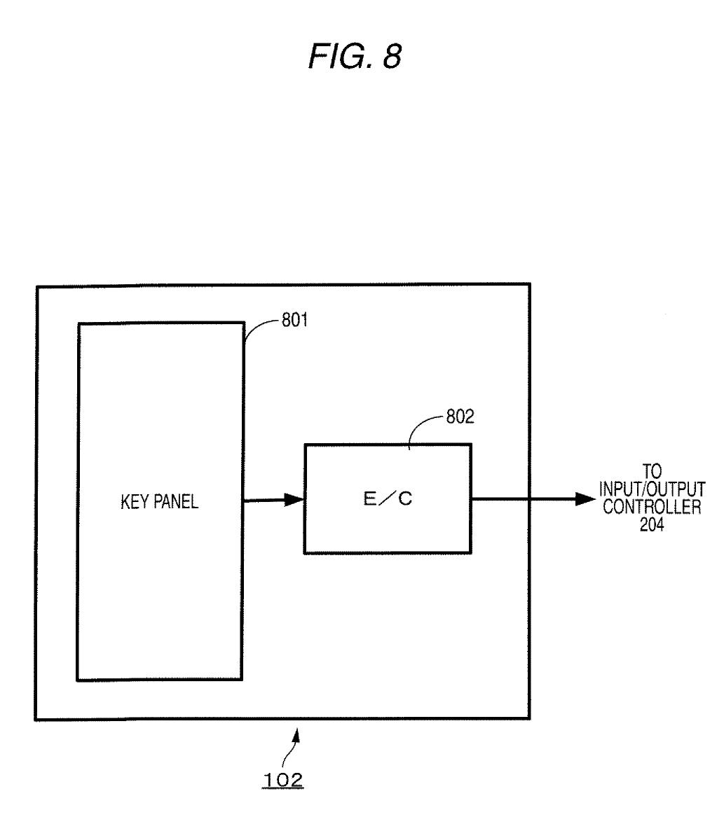

FIG. 8 is a diagram showing an example of a block configuration of the keyboard 102 according to the embodiment.

As shown in FIG. 8, the keyboard 102 is provided with a key panel 801 and an embedded controller (E/C) 801.

The key panel 801 includes a panel having a plurality of key tops of the keyboard 102 and switches that are provided for each of the key tops, which are arranged on the panel. When any one of the key tops are pressed, the switch assigned to the pressed key top is turned on, to thereby output an electrical signal for detecting which key top is pressed.

The E/C 801 is configured by an embedded controller for a particular application, which performs given data processing by being programmed in advance. In the embodiment, the E/C 801 is configured to be input with the electrical signal that is output from the key panel 801 and output a key code corresponding to the input electrical signal to the input/output controller 204.

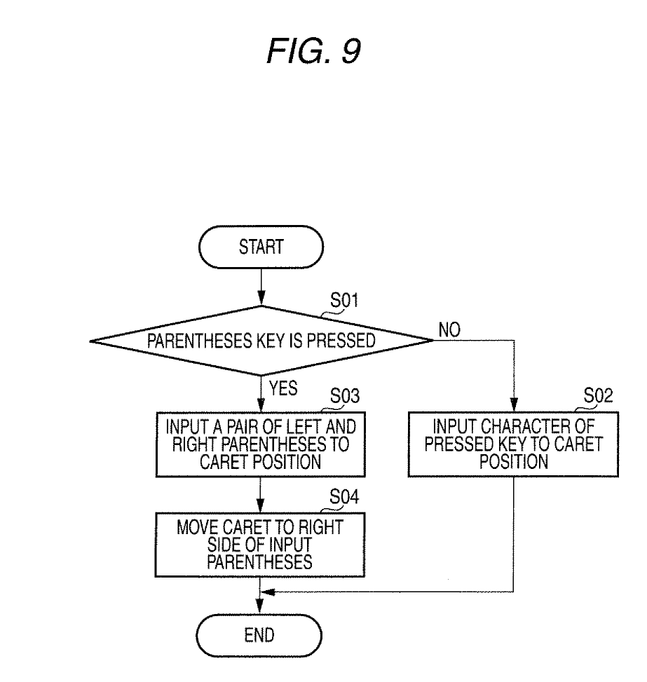

FIG. 9 is a flowchart illustrating an example of key input flow according to the embodiment.

First, the E/C 801 determines, based on the electrical signal output from the key panel 801, whether a parenthesis key, which is provided in the keyboard 102 and assigned for inputting a pair of left and right parenthesis, is pressed or not (Step S01). When the pressed key is not the parenthesis key (No), the E/C 801 outputs a key code for a single character corresponding to a character or symbol printed on the pressed key, to thereby input the character or symbol printed on the pressed key as a normal keyboard input (Step S02).

When the pressed key is the parenthesis key in Step S01 (Yes), the E/C 802 sequentially outputs a plurality of key codes that corresponding to one pair of left and right parentheses configured by two characters (left parentheses and right parentheses). Accordingly, the pair of parentheses is input by a single keystroke (Step S03).

Next, assuming that the caret is moved to the position directly after the input parentheses (right next to the right parentheses), the position of the caret is moved to a position for inputting characters between the pair of the input parentheses (right next to the left parenthesis) (Step S04). In order to perform the caret movement in Step S04, for example, the E/C 802 automatically outputs a control key code to move the caret backward for one character without deleting the character already input.

According to the keyboard 102 thus configured, it is possible to easily input characters or symbols that are generally used as a pair, such as left and right parentheses, with a single keystroke input to the keyboard 102.

In the above description, it is assumed that a mechanical keyboard is used as the keyboard according to the present invention. However, a virtual keyboard, such as an on-screen keyboard, in which an image of a keyboard is displayed on the screen of a display device is also applicable in the same manner. When implementing the input of multiple characters and automatic caret movement as described above for the virtual keyboard, a touchscreen may be provided on a display panel of the display 101, and the operation by the key panel 801 and the E/C 802 may be emulated by the CPU 200 after detecting the keystroke input to the touchscreen by the CPU 200.

The parenthesis key may be freely disposed without depending on the arrangement of the specific keyboard such as a JIS standard keyboard. The present invention may be implemented as any types of apparatuses for inputting characters or symbols exemplified in the present embodiment using keys, and the same or similar advantage may be obtained.

The present invention is not limited to the above-described embodiment, and may be embodied by modifying the components without departing the scope of the present invention. In addition, various types of modification may be made by appropriately combining of the plurality of elements and components described in the above-described embodiment. For example, some components and elements may be omitted.

What is claimed is:

1. A keyboard comprising:
a key panel that comprises:
a plurality of keys that are respectively assigned to input characters, the keys including a specific key that is assigned to input a pair of characters by a single keystroke; and
a plurality of switches that are provided for each of the keys to output an electrical signal unique to each of the keys when the keys are pressed; and
a controller that detects the electrical signal output from the key panel and outputs a key code corresponding to the electrical signal, the controller being configured to operate to:
determine whether the specific key is pressed by detecting the electrical signal; and
output multiple key codes including key codes corresponding to the pair of characters when determined that the specific key is pressed.

2. The keyboard according to claim 1, wherein the pair of characters assigned to the specific key is printed on a key top of the specific key.

3. The keyboard according to claim 1, wherein the pair of characters assigned to the specific key is a pair of left and right parentheses formed by a pair of parentheses of a same type.

4. An input method for inputting characters and symbols using a keyboard, the method comprising:
determining whether a specific key provided on the keyboard is selected, the specific key being assigned to input a pair of characters by a single keystroke; and
output multiple key codes including key codes corresponding to the pair of characters when determined that the specific key is selected.5. The method according to claim 4 further comprising outputting a key code for moving a caret, which indicates a position for a next character to be input, to a position between the pair of the characters.

6. The method according to claim 4, wherein the pair of characters assigned to the specific key is a pair of left and right parentheses formed by a pair of parentheses of a same type.

7. An information processing apparatus comprising:
a keyboard that comprises:
a plurality of keys that are respectively assigned to input characters and symbols, the keys including a specific key that is assigned to input a pair of characters by a single keystroke; and
a plurality of switches that are provided for each of the keys to output an electrical signal unique to each of the keys when the keys are pressed;
a controller that detects the electrical signal output from the key panel and outputs a key code corresponding to the electrical signal, the controller being configured to operate to:
determine whether the specific key is pressed by detecting the electrical signal; and
output multiple key codes including key codes corresponding to the pair of characters when determined that the specific key is pressed; and
a display unit that displays characters corresponding to the key code output from the controller at a caret position.

8. The apparatus according to claim 7, wherein the controller outputs the multiple key codes including a control key code for displaying a caret, which indicates a position for a next character to be input, to a position between the pair of the characters.

9. The apparatus according to claim 7, wherein the pair of characters or symbols is a pair of left and right parentheses formed by a pair of parentheses of a same type.
